(19) United States
(12) Patent Application Publication
(10) Pub. No.: US 2008/0211075 A1
(43) Pub. Date: Sep. 4, 2008

(54) IMAGE SENSOR CHIP SCALE PACKAGE HAVING INTER-ADHESION WITH GAP AND METHOD OF THE SAME

(75) Inventors: Wen-Kun Yang, Hsin-Chu City (TW); Jui-Hsien Chang, Jhudong Township (TW); Hsien-Wen Hsu, Lujhou City (TW); Diann-Fang Lin, Hukou Township (TW)

Correspondence Address: KUSNER & JAFFE;HIGHLAND PLACE SUITE 310, 6151 WILSON MILLS ROAD, HIGHLAND HEIGHTS, OH, 44143, US

(73) Assignee: Advanced Chip Engineering Technology Inc.

(21) Appl. No.: 11/950,921

(22) Filed: Dec. 5, 2007

Related U.S. Application Data
(63) Continuation-in-part of application No. 11/753,006, filed on May 24, 2007.
Application No. 11/753,006 is a continuation-in-part of application No. 11/539,215, filed on Oct. 6, 2006, now Pat. No. 7,335,870.
Application No. 11/539,215 is a continuation-in-part of application No. 11/647,217, filed on Dec. 29, 2006.

(51) Int. Cl. H01L 23/04; H01L 21/71

(52) U.S. Cl. 257/680; 438/116; 257/E23.181; 257/E21.536

(57) ABSTRACT

A structure of semiconductor device package having inter-adhesion with gap comprising: a chip with bonding pads and a sensor area embedded into a substrate with die window and inter-connecting through holes, wherein a RDL is formed over the substrate for coupling between the bonding pads and the inter-connecting through holes; a multiple rings (dam bar) formed over the substrate, the RDL, and the bonding pads area except the sensor area; an adhesive glues fill into the space of the multiple ring except the sensor area; and a transparency material bonded on the top of the multiple ring and the adhesive glues, wherein the adhesive glues adhesion between the transparency material and the multiple rings.

### RELATED APPLICATIONS

The present application is a (continuation-in-part) CIP of pending U.S. application Ser. No. 11/753,006, entitled “CMOS Image Sensor Chip Scale Package with Die Receiving Through-Hole and Method of the Same” (filed May 24, 2007), which is a continuation-in-part (CIP) of co-pending U.S. application Ser. No. 11/539,215 (filed Oct. 6, 2006) and co-pending U.S. application Ser. No. 11/647,217, (filed Dec. 29, 2006). The aforementioned patent applications are commonly assigned to the assignee of the present application, and are fully incorporated herein by reference.

### FIELD OF THE INVENTION

This invention relates to a structure of wafer level package (WLP), and more particularly to a fan-out wafer level package with die receiving through-hole and inter-connecting through holes formed within the substrate to improve the reliability and to reduce the device size.

### DESCRIPTION OF THE PRIOR ART

In the field of semiconductor devices, the device density is increased and the device dimension is reduced, continuously. The demand for the packaging or interconnecting techniques in such high density devices is also increased to fit the situation mentioned above. Conventionally, in the flip-chip attachment method, an array of solder bumps is formed on the surface of the die. The formation of the solder bumps may be carried out by using a solder composite material through a solder mask for producing a desired pattern of solder bumps. The function of chip package includes power distribution, signal distribution, heat dissipation, protection and support . . . and so on. As a semiconductor become more complicated, the traditional package technique, for example lead frame package, flex package, rigid package technique, can't meet the demand of producing smaller chip with high density elements on the chip.

Furthermore, because conventional package technologies have to divide a dice on a wafer into respective dice and then package the die respectively, therefore, these techniques are time consuming for manufacturing process. Since the chip package technique is highly influenced by the development of integrated circuits, therefore, as the size of electronics has become demanding, so does the package technique. For the reasons mentioned above, the trend of package technique is toward ball grid array (BGA), flip chip (FC-BGA), chip scale package (CSP), Wafer level package (WLP) today. “Wafer level package” is to be understood as meaning that the entire packaging and all the interconnections on the wafer as well as other processing steps are carried out before the singulation (dicing) into chips (dice). Generally, after completion of all assembling processes or packaging processes, individual semiconductor packages are separated from a wafer having a plurality of semiconductor dice. The wafer level package has extremely small dimensions combined with extremely good electrical properties.

WLP technique is an advanced packaging technology, by which the die are manufactured and tested on the wafer, and then the wafer is singulated by dicing for assembly in a surface-mount line. Because the wafer level package technique utilizes the whole wafer as one object, not utilizing a single chip or die, therefore, before performing a scribing process, packaging and testing has been accomplished; furthermore, WLP is such an advanced technique so that the process of wire bonding, die mount and under-fill can be omitted. By utilizing WLP technique, the cost and manufacturing time can be reduced, and the resulting structure of WLP can be equal to the die; therefore, this technique can meet the demands of miniaturization of electronic devices.

Though the advantages of WLP technique mentioned above, some issues still exist influencing the acceptance of WLP technique. For instance, the CTE difference (mismatching) between the materials of a structure of WLP and the mother board (PCB) becomes another critical factor to mechanical instability of the structure. A package scheme disclosed by U.S. Pat. No. 6,271,469 suffers the CTE mismatching issue. It is because the prior art uses silicon die encapsulated by molding compound. As known, the CTE of silicon material is 2.3, but the CTE of molding compound is around 40-80. The arrangement causes chip location be shifted during process due to the curing temperature of compound and dielectric layers materials are higher and the inter-connecting pads will be shifted that will causes yield and performance problem. It is difficult to return the original location during temperature cycling (it caused by the epoxy resin property if the curing Temp near/over the Tg). It means that the prior structure package can not be processed by large size, and it causes higher manufacturing cost.

Further, some technical involves the usage of die that directly formed on the upper surface of the substrate. As known, the pads of the semiconductor die will be redistributed through redistribution processes involving a redistribution layer (RDL) into a plurality of metal pads in an area array type. The build up layer will increase the size of the package. Therefore, the thickness of the package is increased. This may conflict with the demand of reducing the size of a chip.

Further, the prior art suffers complicated process to form the “Panel” type package. It needs the mold tool for encapsulation and the injection of mold material. It is unlikely to control the surface of die and compound at same level due to warp after heat curing the compound, the CMP process may be needed to polish the uneven surface. The cost is therefore increased.

Therefore, the present invention provides a fan-out wafer level packaging (FO-WLP) structure with good CTE performance and shrinkage size to overcome the aforementioned problem and also provide the better board level reliability test of temperature cycling.

### SUMMARY OF THE INVENTION

The object of the present invention is to provide a fan-out WLP with excellent CTE performance and shrinkage size.

Another object of the present invention is to provide a fan-out WLP with a substrate having die receiving through-hole (window) for improving the reliability and shrinking the device size.

A structure of semiconductor device package having inter-adhesion with gap comprising: a chip with bonding pads and a sensor area embedded into a substrate with die window and inter-connecting through holes, wherein a RDL is formed over the substrate for coupling between the bonding pads and the inter-connecting through holes; a multiple rings (dam bar) formed over the substrate, the RDL, and the bonding pads area except the sensor area; an adhesive glues fill into the space of the multiple ring except the sensor area; and a transparency material bonded on the top of the multiple ring and the adhesive glues, wherein the adhesive glues adhesion between the transparency material and the multiple rings.

The RDL comprises Ti/Cu/Au alloy or Ti/Cu/Ni/Au alloy. The material of the substrate includes epoxy type FR5, FR4, BT, silicon, PCB (print circuit board) material, glass or ceramic, alloy or metal. Preferably the thickness of the multiple ring (dam bar) is over 20 um. The materials of the multiple ring (dam bar) includes the polymer modified resin, rubber resin with elastic properties. The elongation of the multiple ring is preferably over 30%. A dielectric layer is formed under the RDL, the dielectric layer includes an elastic dielectric layer, a photosensitive layer, a silicone dielectric based layer, a siloxane polymer (SINR) layer, a polyimides (PI) layer or silicone resin layer. The materials of adhesive glues include UV or thermal type with elastic property. The elongation of adhesive glues is preferably over 50%. The transparent material includes glass, crystal or high transparency plastic.

### BRIEF DESCRIPTION OF THE DRAWINGS

FIG. 1 illustrates a cross-sectional view of a structure of fan-out WLP (LGA type) according to the present invention.

FIG. 1A illustrates a cross-sectional view of a structure of the micro lens according to the present invention.

FIG. 2 illustrates a cross-sectional view of a structure of fan-out WLP (BGA type) according to the present invention.

FIG. 3 illustrates a cross-sectional view of the substrate according to the present invention.

FIG. 4 illustrates a cross-sectional view of the combination of the substrate and the glass carrier according to the present invention.

FIG. 5 illustrates a top view of the substrate according to the present invention.

FIG. 6 illustrates a cross-sectional view of the CIS module according to the present invention.

FIG. 7 illustrates a schematic diagram showing a glass attached on a tape according to the present invention.

FIG. 8 illustrates flow chart according to the present invention.

FIG. 9 illustrates a cross-sectional view of a structure according to the present invention.

FIG. 10a illustrates the top view of the substrate before bonding, and after printing adhesion glue according to the present invention.

FIG. 10b illustrates the top view of the substrate after bonding transparency material thereon according to the present invention.

FIG. 10c illustrates the top view of the substrate before cutting according to the present invention.

### DESCRIPTION OF THE PREFERRED EMBODIMENT

The invention will now be described in greater detail with preferred embodiments of the invention and illustrations attached. Nevertheless, it should be recognized that the preferred embodiments of the invention is only for illustrating. Besides the preferred embodiment mentioned here, present invention can be practiced in a wide range of other embodiments besides those explicitly described, and the scope of the present invention is expressly not limited expect as specified in the accompanying claims.

The present invention discloses a structure of fan-out WLP utilizing a substrate having predetermined terminal contact metal pads 3 formed thereon and a pre-formed die (window) receiving through hole 4 formed into the substrate 2. A die is disposed within the die receiving through hole of the substrate and attached on core paste material, for example, an elastic core paste material is filled into the space between die edge and side wall of die receiving through hole of the substrate and/or under the die. A photosensitive material is coated over the die and the pre-formed substrate (includes the core paste area). Preferably, the material of the photosensitive material is formed of elastic material.

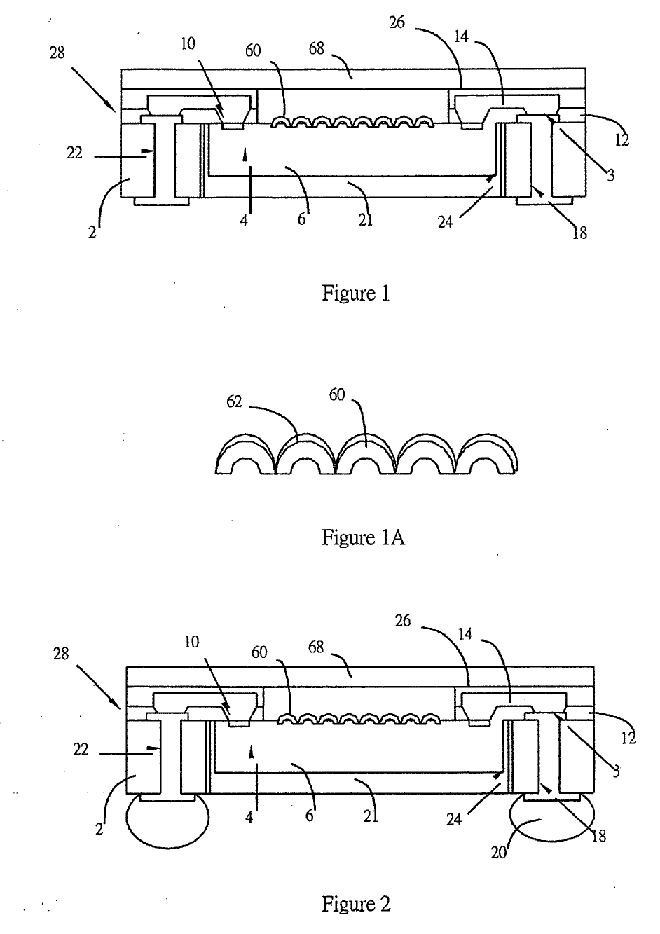

FIG. 1 illustrates a cross-sectional view of Fan-Out Wafer Level Package (PO-WLP) in accordance with one embodiment of the present invention. As shown in the FIG. 1, the structure of FO-WLP includes a substrate 2 having a first terminal contact conductive pads 3 (for organic substrate) and die receiving through holes 4 formed therein to receive a die 6. The die receiving through holes 4 is formed from the upper surface of the substrate through the substrate to the lower surface. The die receiving through hole 4 is pre-formed within the substrate 2. The core paste material 21 is vacuum printed or coated under the lower surface of the die 6, thereby sealing the die 6. The core paste 21 is also refilled within the space (gap) between the die edge 6 and the sidewalls of the through holes 4. A conductive (metal) layer 24 is coated on the sidewall of the die receiving through holes 4 as optional process to improve the adhesion between the die 6 and the substrate 2.

The die 6 is disposed within the die receiving through holes 4 on the substrate 2. As know, contact pads (Bonding pads) 10 are formed on the die 6. A photosensitive layer or dielectric layer 12 is formed over the die 6 and the upper surface of substrate. Pluralities of openings are formed within the dielectric layer 12 through the lithography process or exposure and develop procedure. The pluralities of openings are aligned to the contact pads (or I/O pads) 10 and the first terminal contact conductive pads 3 on the upper surface of the substrate, respectively. The RDL (redistribution layer) 14, also referred to as conductive trace 14, is formed on the dielectric layer 12 by removing selected portions of metal layer formed over the layer 12, wherein the RDL 14 keeps electrically connected with the die 6 through the I/O pads 10 and the first terminal contact conductive pads 3. The substrate 2 further comprises connecting through holes 22 formed within the substrate 2. The first terminal contact metal pads 3 are formed over the connecting through holes 22. The conductive material is re-filled into the connecting through holes 22 for electrical connection. Second terminal contact conductive pads 18 are located at the lower surface of the substrate 2 and under the connecting through holes 22 and connected to the first terminal contact conductive pads 3 of the substrate. A scribe line 28 is defined between the package units for separating each unit, optionally, there is no dielectric layer over the scribe line for better cutting quality. A protection layer 26 is employed to cover the RDL 14.

It should be noted that the die 6 including a micro lens area 60 formed on the die 6. The micro lens area 60 has a second protection layer 62 formed thereon, please refer to FIG. 1A; the second protection layer 62 was done by coating process and the properties of the protection layer 62 with water repellency and oil repellency to protect the particle contamination during process.

The dielectric layer 12 and the core paste material 21 act as buffer area that absorbs the thermal mechanical stress between the die 6 and substrate 2 during temperature cycling due to the dielectric layer 12 has elastic property. The aforementioned structure constructs LGA type package.

Transparent base 68, for example glass cover, is formed on the protection layer 26 to cover the second protection layer 62 on the micro lens area 60, thereby creating a gap (cavity) between the glass cover 68 and micro lens area 60. The transparent base 68 may be the same as the package size (foot print) or slight bigger than the package (substrate after cutting) size. The protection layer 26, preferable the elastic materials, can be employed to adhere to the glass cover 68.

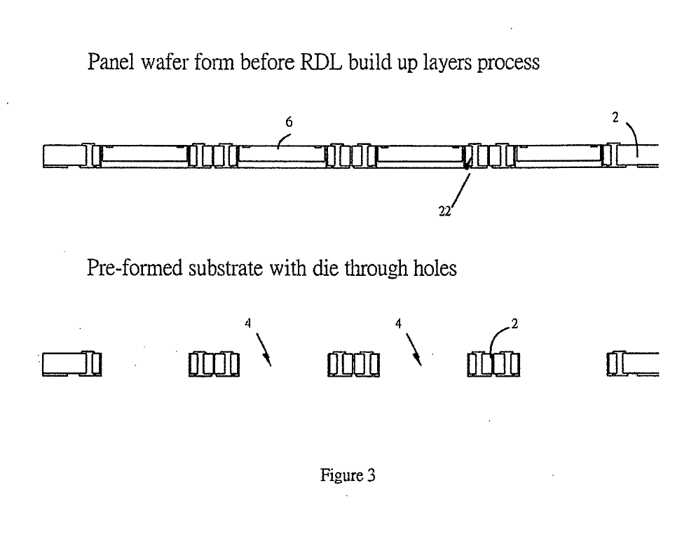

An alternative embodiment can be seen in FIG. 2, conductive balls 20 are formed on the second terminal contact conductive pads 18. This type is called BGA type, and the connecting through hole 22 can be located in edge site of substrate. The other parts are similar to FIG. 1, therefore, the detailed description is omitted. The terminal pads 18 may act as the UBM (under ball metal) under the BGA scheme in the case. Pluralities of contact conductive pads 3 are formed on the upper surface of the substrate 2 and under the RDL 14.

Preferably, the material of the substrate 2 is organic substrate likes epoxy type FR5, BT, PCB with defined through holes or Cu metal with pre etching circuit. Preferably, the CTE is the same as the one of the mother board (PCB). Preferably, the organic substrate with high Glass transition temperature (Tg) are epoxy type FR5 or BT (Bismaleimide triazine) type substrate. The Cu metal (CTE around 16) can be used also. The glass, ceramic, silicon can be used as the substrate. The elastic core paste is formed of silicone rubber, resin elastic materials.

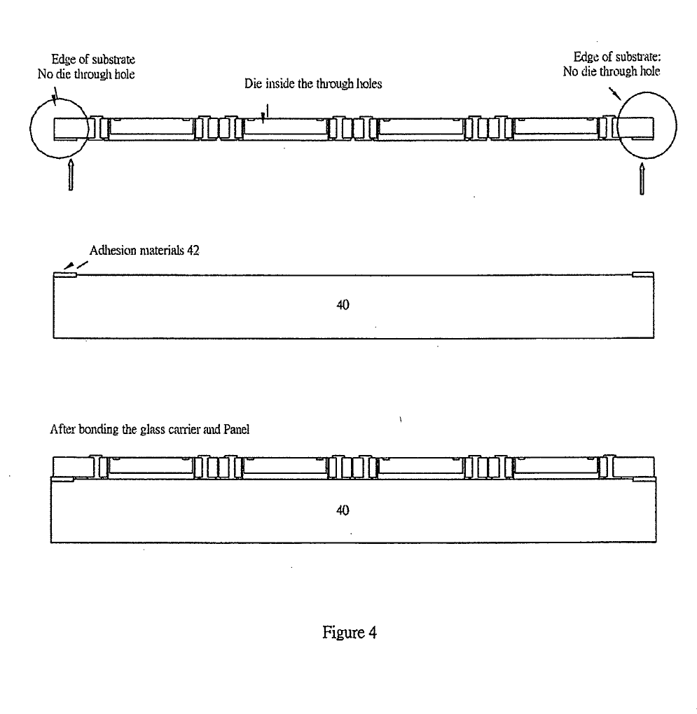

The substrate could be round type such as wafer type, the diameter could be 200, 300 mm or higher. It could be employed for rectangular type such as panel form. The substrate 2 is pre-formed with die receiving through holes 4. The scribe line 28 is defined between the units for separating each unit. Please refer to FIG. 3, it shows that the substrate 2 includes a plurality of pre-formed die receiving through hole 4 and the connecting through holes 22. Conductive material is re-filled into the connecting through holes 22, thereby constructing the connecting through hole structures.

In one embodiment of the present invention, the dielectric layer 12 is preferably an elastic dielectric material which is made by silicone dielectric based materials comprising siloxane polymers (SINR), Dow Corning WL5000 series, and the combination thereof. In another embodiment, the dielectric layer is made by a material comprising, polyimides (PI) or silicone resin. Preferably, it is a photosensitive layer for simple process.

In one embodiment of the present invention, the elastic dielectric layer is a kind of material with CTE larger than 100 (ppm/° C.), elongation rate about 40 percent (preferably 30 percent-50 percent), and the hardness of the material is between plastic and rubber. The thickness of the elastic dielectric layer 12 depends on the stress accumulated in the RDL/dielectric layer interface during temperature cycling test.

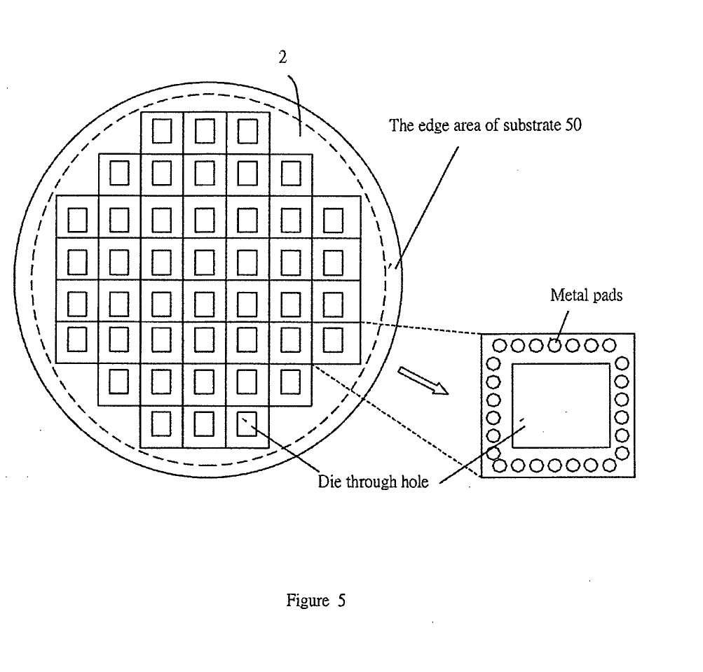

FIG. 4 illustrate the tool 40 for (Glass or CCL) carrier and the substrate 2. Adhesion materials 42 such as temporary adhesion material are formed at the periphery area of the tool 40. In one case, the tool could be made of glass or CCL (Copper Clad Laminate) with the shape of panel form. The connecting through holes structures will not be formed at the edge of the substrate. The lower portion of FIG. 4 illustrates the combination of the tool and the substrate. The panel will be adhesion with the (glass or CCL) carrier, it will stick and hold the panel during process.

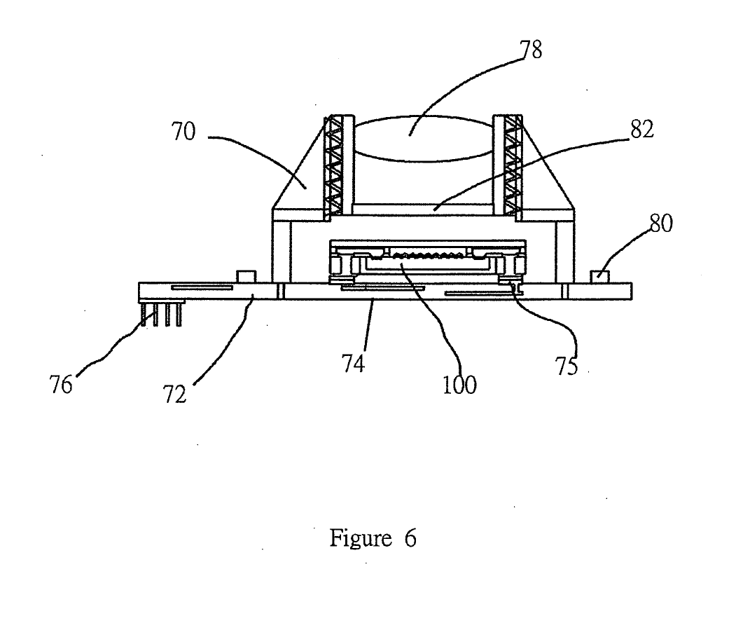

FIG. 5 illustrates the top view of the substrate having die receiving through holes 4. The edge area 50 of substrate does not have the die receiving through holes, it is employed for sticking (adhesion) the (glass or CCL) carrier during WLP process. After the WLP process is completed, the substrate 2 will be cut (releasing) along the dot line from the (glass or CCL) carrier, it means that the inside area of dot line will be processed by the sawing process for package singulation.

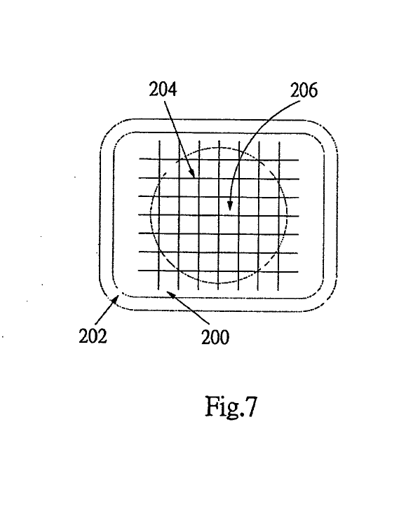

Please refer to FIG. 6, the aforementioned device package may be integrated into a CIS module having a lens holder 70 on a print circuit board 72 with conductive traces 74. A connector 76 is formed at one end of the print circuit board 72. Preferably, print circuit board 72 includes flexible print circuit board (FPC). The device package 100 is formed on the print circuit board 72 via the contact metal pads 75 on FPC and within the lens holder 70 by solder join (paste or Balls) by using SMT process. A lens 78 is formed atop of the holder 70 and IR filter 82 (optional) is located within the lens holder 70 and between the device 100 and the lens. At least one passive device 80 may be formed on the FPC within the lens holder 70 or outside the lens holder 70.

The silicon die (CTE is ˜2.3) is packaged inside the package. FR5 or BT organic epoxy type material (CTE ˜16) is employed as the substrate and its CTE is the same as the PCB or Mother Board. The space (gap) between the die and the substrate is filled with filling material (prefer the elastic core paste) to absorb the thermal mechanical stress due to CTE mismatching (between die and the epoxy type FR5/BT). Further, the dielectric layers 12 include elastic materials to absorb the stress between the die pads and the PCB. The RDL metal is Cu/Au materials and the CTE is around 16 the same as the PCB and organic substrate, and the UBM 18 of contact bump is located under the terminal contact metal pads 3 of substrate. The metal land of PCB is Cu composition metal, the CTE of Cu is around 16 that is match to the one of PCB. From the description above, the present invention may provide excellent CTE (fully matching in X/Y direction) solution for the WLP.

Apparently, CTE matching issue under the build up layers (PCB and substrate) is solved by the present scheme and it provides better reliability (no thermal stress in X/Y directions for terminal pads (solder balls/bumps) on the substrate during on board level condition) and the elastic DL is employed to absorb the Z direction stress. The space (gap) between chip edge and sidewall of through holes of substrate can be used to fill the elastic dielectric materials to absorb the mechanical/thermal stress.

In one embodiment of the invention, the material of the RDL comprises Ti/Cu/Au alloy or Ti/Cu/Ni/Au alloy; the thickness of the RDL is between 2 um_and_{—}15 um. The Ti/Cu alloy is formed by sputtering technique also as seed metal layers, and the Cu/Au or Cu/Ni/Au alloy is formed by electroplating; exploiting the electro-plating process to form the RDL can make the RDL thick enough and better mechanical properties to withstand CTE mismatching during temperature cycling. The metal pads can be Al or Cu or combination thereof. If the structure of FO-WLP utilizes SINR as the elastic dielectric layer and Cu as the RDL, according the stress analysis not shown here, the stress accumulated in the RDL/dielectric layer interface is reduced.

As shown in FIG. 1-2, the RDLs fan out from the die and they communicate toward the second terminal pads downwardly. It is different from the prior art technology, the die 6 is received within the pre-formed die receiving through hole of the substrate, thereby reducing the thickness of the package. The prior art violates the rule to reduce the die package thickness. The package of the present invention will be thinner than the prior art. Further, the substrate is pre-prepared before package. The through hole 4 is pre-determined. Thus, the throughput will be improved than ever. The present invention discloses a fan-out WLP with reduced thickness and good CTE matching performance.

The present invention includes preparing a substrate (preferably organic substrate FR4/FR5/BT) and contact metal pads are formed on top surface. The die receiving through hole is formed with the size larger than die size plus >100 um/side. The depth is the same (or about 25 um thick than) with the thickness of dice thickness.

The protection layer of micro lens is formed on the processed silicon wafer, it can improve the yield during fan-out WLP process to avoid the particle contamination. The next step is lapping the wafer by back-lapping to desired thickness. The wafer is introduced to dicing procedure to separate the dice.

Thereafter, process for the present invention includes providing a die redistribution (alignment) tool with alignment pattern formed thereon. Then, the patterned glues is printed on the tool (be used for sticking the surface of dice and substrate), followed by using pick and place fine alignment system with flip chip function to redistribute the desired dice on the tool with desired pitch. The patterned glues will stick the chips (active surface side) on the tool. Subsequently, the substrate (with die receiving through holes) is bound on the tool (stuck by patterned glues) and followed by printing elastic core paste material on the space (gap) between die and side walls of through holes of the (FR5/BT) substrate and the die back side. It is preferred to keep the surface of the core paste and the substrate at the same level. Next, the curing process is used to cure the core paste material and bonding the (glass or CCL) carrier by adhesion material. The panel bonder is used to bond the base on to the substrate and die back side. Vacuum bonding is performed, followed by separating the tool from the panel wafer.

Once the die is redistributed on the substrate (panel base), then, a clean up procedure is performed to clean the dice surface by wet and/or dry clean. Next step is to coat the dielectric materials on the surface of panel. Subsequently, lithography process is performed to open via (contact metal pads) and Al bonding pads and micro lens area or the scribe line (optional). Plasma clean step is then executed to clean the surface of via holes and Al bonding pads. Next step is to sputter Ti/Cu as seed metal layers, and then Photo Resistor (PR) is coated over the dielectric layer and seed metal layers for forming the patterns of redistributed metal layers (RDL). Then, the electro plating is processed to form Cu/Au or Cu/Ni/Au as the RDL metal, followed by stripping the PR and metal wet etching to form the RDL metal trace. Subsequently, the next step is to coat or print the top dielectric layer and to open the micro lens area or to open the scribe line (optional).

The micro lens area can be exposed after the dielectric layer is formed and after the formation of the protection layer.

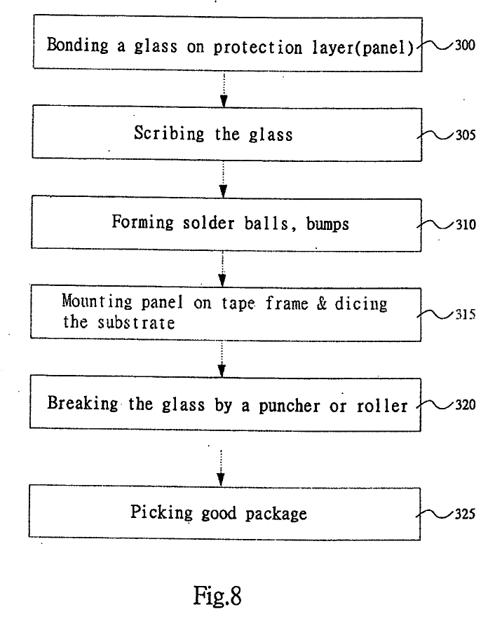

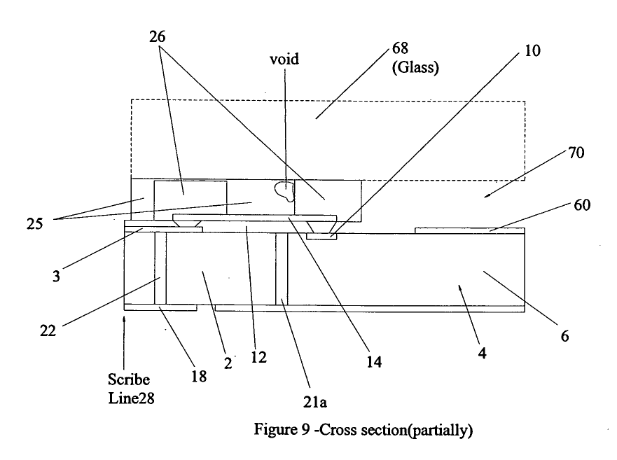

The present invention provides a method to form the transparent base (glass), for example glass cover 70 of FIGS. 1 and 2, without the usage of the lithography process. Referring to FIG. 7 and FIG. 8, the glass is processed by the panel bonder (in vacuum condition) with around 50 micron meters accuracy alignment to bond the glass together with panel. Preferably, the process is performed by vacuum bonding, therefore, the cavity will be generated, please refer to step 300. The glass 202 may be a round type or rectangular type. The glass is optionally coated with IR coating and the thickness of the coating is around 50-200 micron meters.

In step 305 of FIG. 8, the next step is to scribe the glass 202 with scribe lines 204 on the glass, as shown in FIG. 7. The scribe lines that are constructed by vertical lines and horizontal lines form a checkerboard pattern, thereby forming cover zones 206 divided by each scribe lines.

Then, in step 310, printing the ball placement or solder paste on the second contact metal 18, the heat re-flow procedure is performed to re-flow on the ball side (for BGA type). The testing is executed. Panel wafer level final testing is performed by using vertical or epoxy probe card to contact the contact metal via. After the testing, in step 315, mounting the panel (with transparent base—glass) on the blue tape frame form, the substrate 200 is sawed from the lower surface site to separate the substrate into individual units.

The next step 320 is to break the glass from the lower surface site of the substrate by a rubber puncher or roller. Then, in step 325, the packages are respectively picked and placed the package on the tray or tape and reel.

In an individual CIS (CMOS Image Sensor) package module, a sensor package with transparent base is attached on the top surfaces of a fan-out wafer level package, and a package is soldering on the Print Circuit Board by SMT process. A lens holder maybe is fixed on the printed circuit board to hold a lens. A filter, such as an IR CART, is fixed to the lens holder. Alternatively, the filter may comprise a filtering layer, for example IR filtering layer, formed upper or lower surface of the glass to act as a filter. In one embodiment, IR filtering layer comprises TiO2, light catalyzer. The glass may prevent the micro lens from particle containment. The user may use liquid or air flush to remove the particles on the glass without damaging the micron lens.

Hence, according to the present invention, the aforementioned package structure has the advantages list as follow: the BGA or LGA package structure of the present invention can prevent the micro lens from particle contamination. Moreover, CMOS/CCD image sensor package module structure may be directly cleaned to remove particle contamination. The process of manufacturing of the BGA or LGA package structure of the present invention is significantly simple.

The advantages of the present inventions are:

The process is simple for forming Panel wafer type and is easy to control the roughness of panel surface. The thickness of panel is easy to be controlled and die shift issue will be eliminated during process. The injection mold tool is omitted and warp, CMP polish process will not be introduced either. The panel wafer is easy to be processed by wafer level packaging process.

The substrate is pre-prepared with pre-form die receiving through holes, inter-connecting through holes and terminal contact metal pads (for organic substrate); the size of through hole is equal to die size plus around >100 um per/side; it can be used as stress buffer releasing area by filling the elastic core paste materials to absorb the thermal stress due to the CTE between silicon die and substrate (FR5/BT)) is difference. The packaging throughput will be increased (manufacturing cycle time was reduced) due to apply the simple build up layers on top the surface of die. The terminal pads are formed on the opposite side of the dice active surface.

The dice placement process is the same as the current process. Elastic core paste (resin, epoxy compound, silicone rubber, etc.) is refilled the space between the dice edge and the sidewall of the through holes for thermal stress releasing buffer in the present invention, then, vacuum heat curing is applied. CTE mismatching issue is overcome during panel form process (using the carrier with matching CTE that close to substrate). Only silicone dielectric material (preferably SINR) is coated on the active surface and the substrate (preferably FR45 or BT) surface. The contact pads are opened by using photo mask process only due to the dielectric layer (SINR) is photosensitive layer for opening the contacting open. The die and substrate be bonded together with carrier. The reliability for both package and board level is better than ever, especially, for the board level temperature cycling test, it was due to the CTE of substrate and PCB mother board are identical, hence, no thermal mechanical stress be applied on the solder bumps/balls; the previous failure mode (solder ball crack) during temperature cycling on board test were not obvious. The cost is low and the process is simple. It is easy to form the multi-chips package as well.

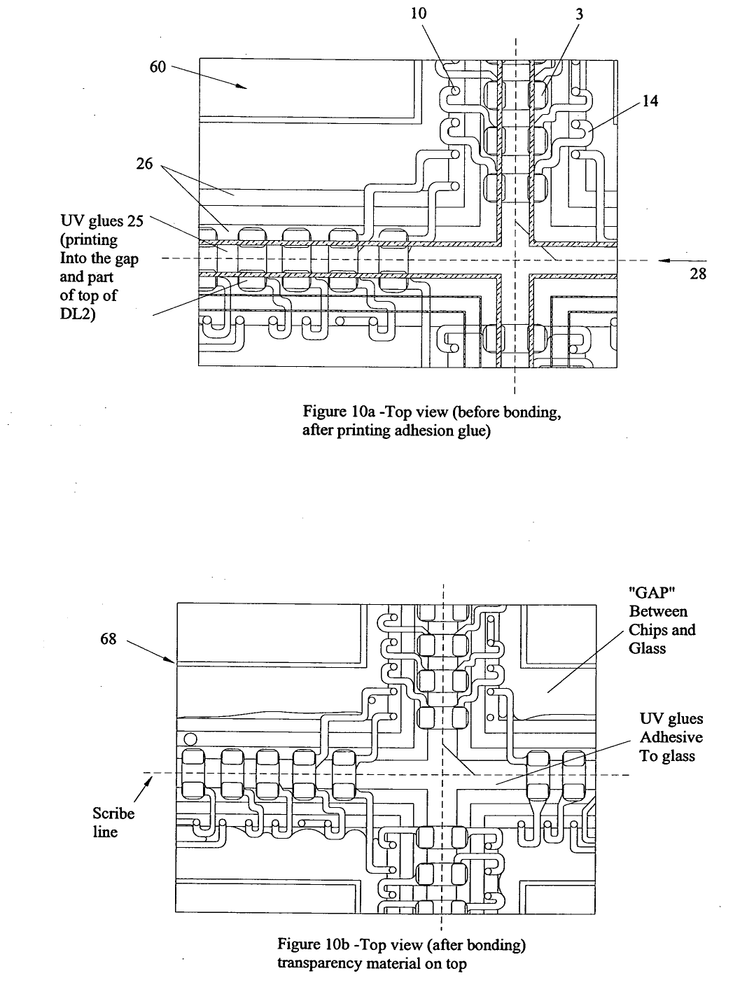

Alternatively embodiment is shown in FIG. 9, it shows a part (cross section) of the package as in FIG. 1-2. The structure of FO-WLP includes a core (substrate) 2 having a first terminal contact conductive pads 3 (for organic substrate) and die receiving through holes (window) 4 formed therein to receive a die 6. The die receiving through holes 4 is formed from the upper surface of the substrate through the substrate to the lower surface. The die receiving through hole 4 is pre-formed within the core (substrate) 2. The die adhesion material (DAM) or die adhesion film (DAF) 21a is printed or coated under the lower surface of the die 6 and sidewall of the die, thereby sealing the die 6. The die adhesion material 21a is also refilled within the space (gap) between the die edge 6 and the sidewalls of the through holes 4. Preferably, the DAF includes the composition of (i) epoxy resin, phenol resin; (2) acrylic rubber; (3) Si filler. The function of epoxy resin, phenol resin is heat resistance and has the properties of low CTE. The function of acrylic rubber is stress reduction and the function of Si filler is cohesion strength. Therefore, the DAF may have the high reflow resistance, TCT resistance and the increase of adhesion strength. The dimension of the Si particles in Si filer is less than 1 micron-meter. The weight percentage of Si filler is less than 10 percentages.

The die 6 is disposed within the die receiving through holes 4 on the substrate 2. As know, contact pads (Bonding pads) 10 are formed on the die 6. A photosensitive layer or first dielectric layer 12 is formed over the die 6 and the upper surface of core 2 to expose the micro-lens area. Pluralities of openings are formed within the first dielectric layer 12 through the lithography process or exposure and develop procedure. The pluralities of openings are aligned to the contact pads (or I/O pads) 10 and the first terminal contact conductive pads 3 on the upper surface of the substrate, respectively. The RDL (redistribution layer) 14, also referred to as conductive trace 14, is formed on the first dielectric layer 12 by removing selected portions of metal layer formed over the layer 12, wherein the RDL 14 keeps electrically connected with the die 6 through the I/O pads 10 and the first terminal contact conductive pads 3. The substrate 2 further comprises connecting through holes 22 formed within the substrate 2. The first terminal contact metal pads 3 are formed over the inter-connecting through holes 22. The conductive material is re-filled into the connecting through holes 22 for electrical connection. Second terminal contact conductive pads 18 are located at the lower surface of the substrate 2 and under the connecting through holes 22 and connected to the first terminal contact conductive pads 3 of the substrate. A scribe line 28 is defined between the package units for separating each unit, optionally, there is no dielectric layer over the scribe line for better cutting quality. A second dielectric layer 26 having elastic property is partially formed to cover the RDL 14. A UV glue layer 25 having elastic property is formed over the core and within the openings of the second dielectric layer 26 except the micro lens (sensor) 60 area.

It should be note that the die 6 including a micro lens area 60 formed on the die 6. The micro lens area 60 may has a second protection layer (as above embodiment) formed thereon, please refer to FIG. 1A; the second protection layer 62 was done by coating process and the properties of the protection layer 62 with water repellency and oil repellency to protect the particle contamination during process. The first, second dielectric layer and the DAF 21 act as buffer area that absorbs the thermal mechanical stress between the die 6 and substrate 2 during temperature cycling due to the dielectric and UV layer has elastic property.

Transparent cover 68, for example glass cover, is formed on the second dielectric layer 26 to expose the micro lens area 60, thereby creating a gap (cavity) 70 between the glass cover 68 and micro lens area 60. The transparent cover 68 may be the same as the package size (foot print) or slight bigger or smaller than the package (substrate after cutting) size.

The present invention includes preparing a core or substrate (preferably organic substrate, FR4/FR5/BT) and contact metal pads are formed on top surface. The die receiving through hole is formed with the size larger than die size plus >100 um/side. The depth is the same (or about 25 um thick than) with the thickness of dice thickness. A wafer lapping step is processed by back-lapping to desired thickness. The wafer is introduced to dicing procedure to separate the dice.

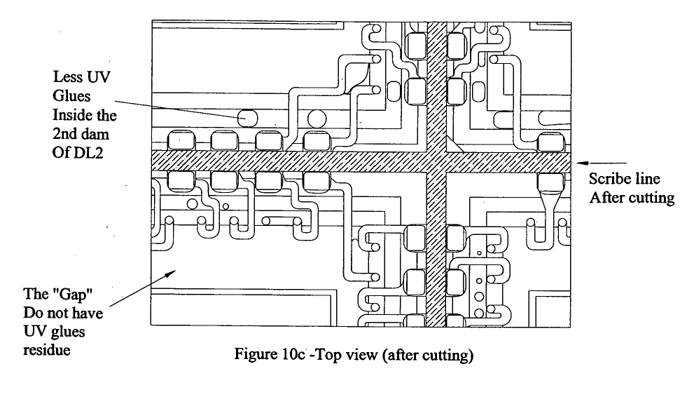

The process of forming the embodiment includes steps of: preparing a substrate w/die receiving window and inter-connecting through holes with contact metal pads on both side; aligning and bonding the substrate onto the die placement tools and disposing chip into die receiving window onto the die placement tools. Die attached material is formed into the gap between die edge and side wall of window and the die back side, followed by forming the DL1 (first dielectric layer) to open the bonding pads and 1st contact pads and forming RDL to couple the bonding pads to 1st contact pads. A DL2 (second dielectric layer) is formed with double ring patterns and higher thickness then DL1. It means that the second dielectric layer includes double pattern. UV glues (stencil) is printed into the space of double ring area. The nest step is to bond the transparency materials with “Panel” together by vacuum bonding with force, followed by curing the UV glues. The nest step is to cut the panel (Glass and substrate) to singulate the package. FIG. 10a illustrates the top view of the substrate before bonding, and after printing adhesion glue. FIG. 10b illustrates the top view of the substrate after bonding transparency material thereon. FIG. 10c illustrates the top view of the substrate after cutting.

Although preferred embodiments of the present invention have been described, it will be understood by those skilled in the art that the present invention should not be limited to the described preferred embodiments. Rather, various changes and modifications can be made within the spirit and scope of the present invention, as defined by the following claims.

Having described the invention, the following is claimed:

1. A structure of semiconductor device package having inter-adhesion with gap comprising:
a chip with bonding pads and a sensor area embedded into a substrate with die window and inter-connecting through holes, wherein a RDL is formed over said substrate for coupling between said bonding pads and said inter-connecting through holes;
a multiple rings (dam bar) formed over said substrate, said RDL, and said bonding pads area except said sensor area;
an adhesive glues fill into the space of said multiple ring except said sensor area; and
a transparency material bonded on the top of said multiple ring and said adhesive glues, wherein said adhesive glues adhesion between said transparency material and said multiple rings.

2. The structure of claim 1, wherein said RDL comprises Ti/Cu/Au alloy or Ti/Cu/Ni/Au alloy.

3. The structure of claim 1, wherein the material of said substrate includes epoxy type FR5 or FR4.

4. The structure of claim 1, wherein the material of said substrate includes BT, silicon, PCB (print circuit board) material, glass or ceramic.

5. The structure of claim 1, wherein the material of said substrate includes alloy or metal.

6. The structure of claim 1, wherein the thickness of said multiple ring (dam bar) over 20 um.

7. The structure of claim 1, wherein the materials of said multiple ring (dam bar) includes the polymer resin, rubber resin with elastic properties.

8. The structure of claim 7, wherein the elongation of said multiple ring is over 30%.

9. The structure of claim 1, further including a dielectric layer formed under said RDL, said dielectric layer includes an elastic dielectric layer, a photosensitive layer, a silicone dielectric based layer, a siloxane polymer (SINR) layer, a polyimides (PI) layer or silicone resin layer.

10. The structure of claim 1, wherein the materials of adhesive glues includes UV or thermal type with elastic property.

11. The structure of claim 1, wherein the elongation of adhesive glues is over 50%.

12. The structure of claim 1, wherein said transparent material includes glass, crystal or high transparency plastic.

13. A method for forming semiconductor device package comprising:
preparing a substrate with a die receiving window and inter-connecting through holes with contact metal pads on both side;
aligning and bonding said substrate onto a die placement tool and disposing a chip into said die receiving window onto said die placement tool;
forming die attached material into a gap between die edge and side wall of said die receiving window and die back side, followed by forming a first dielectric layer to open bonding pads and contact pads;
coupling RDL to said bonding pads and said contact pads;
forming a second dielectric layer with multiple ring patterns and higher thickness then said first dielectric layer;
printing UV glues into the space of said multiple ring area; and
bonding a transparency materials with a panel together by vacuum bonding.

14. The method of claim 13, further comprising the process step to cutting said transparency materials and said substrate to singulate the package.

15. The method of claim 13, wherein said RDL comprises Ti/Cu/Au alloy or Ti/Cu/Ni/Au alloy.

16. The method of claim 13, wherein the material of said substrate includes epoxy type FR5 or FR4.

17. The method of claim 13, wherein the material of said substrate includes BT, silicon, PCB (print circuit board) material, glass or ceramic.

18. The method of claim 13, wherein the material of said substrate includes alloy or metal.

19. The method of claim 13, wherein the thickness of said multiple ring (dam bar) over 20 um.

20. The method of claim 13, wherein the materials of said multiple ring (dam bar) includes the polymer resin, rubber resin with elastic properties.

21. The method of claim 20, wherein the elongation of said multiple ring is over 30%.

22. The method of claim 13, further including a dielectric layer formed under said RDL, said dielectric layer includes an elastic dielectric layer, a photosensitive layer, a silicone dielectric based layer, a siloxane polymer (SINR) layer, a polyimides (PI) layer or silicone resin layer.

23. The method of claim 13, wherein the materials of adhesive glues includes UV or thermal type with elastic property.

24. The method of claim 23, wherein the elongation of adhesive glues is over 50%.

25. The method of claim 13, wherein said transparent material includes glass, crystal or high transparency plastic.
